(19) United States
(12) Patent Application Publication
(10) Pub. No.: US 2006/0166510 A1
(43) Pub. Date: Jul. 27, 2006

(54) Semiconductor manufacturing method for die bonding

(76) Inventor: Masao Okayama, Ryugasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/338,782

(22) Filed: Jan. 25, 2006

(30) Foreign Application Priority Data
Jan. 26, 2005 (JP) 2005-018358

(51) Int. Cl. H01L 21/302

(52) U.S. Cl. 438/745

(57) ABSTRACT

The present invention has a pump system having a gear pump to which a gear structure, having a pump gear and a driving gear concentrically and integrally formed with each other, is incorporated; a main control section for controlling this pump system; and a stage that can support a plate-like member such as a lead frame. In the gear pump, driving force is given to the driving gear to rotate the pump gear, whereby a paste is applied on the plate-like member. The use of the gear pump allows the reduction in cost for manufacturing and assembling the gears, thereby being capable of reducing manufacturing cost.

### CROSS-REFERENCE TO RELATED APPLICATION

The present application claims priority from Japanese patent application No. 2005-018358 filed on Jan. 26, 2005, the content of which is hereby incorporated by reference into this application.

### BACKGROUND OF THE INVENTION

This invention is related to a semiconductor manufacturing technique, and more particularly, to a technique effectively applicable to manufacture using a gear pump.

A viscous fluid applying device has a discharge nozzle, nozzle rotating device, screw pump, screw rotating device and adhesive supplying device on a Z-axis slide that is moved in a direction parallel to the surface of a print wiring board by an XY direction moving robot. The discharge nozzle is concentrically provided at a pump housing, and the screw is rotatably provided in a screw chamber, wherein an adhesive is supplied by the adhesive supplying device. (e.g., see Patent Reference 1).

In a pushing device for viscous fluid, a bottom cover slidably arranged in a cylindrical chamber is pushed toward the leading end of the chamber, whereby viscous fluid such as grease or coking agent is discharged from a discharge port at the leading end (e.g., see Patent Reference 2).

A fluid discharge amount control device controls such that fluid of designated amount is discharged at a designated discharge time with high precision (e.g., see Patent Reference 3).

In a pattern forming method in a display panel having an effective display area that forms a pattern and a non-effective display area that does not form a pattern at the outer periphery of the effective display area, a dispenser that can vary a flow rate is used, so that, when a discharge nozzle moves on the non-effective display area of the display panel, the discharge of a paste is promptly broken (e.g., see Patent Reference 4).

In a pattern forming method of a display panel, when a dispenser is relatively moved on an effective display area of a substrate having the effective display area forming a paste layer and a non-effective display area which does not form the paste layer at the outside of the effective display area, the paste is discharged, while when it moves on the non-effective display area, the discharge of the paste is broken (e.g., see Patent Reference 5).

A gear pump is configured such that a pair of gears that transport active material paste for a battery electrode rotates so as to keep a gap between respective tooth surfaces at the meshed section, thereby avoiding a collapsing action at the meshed section (e.g., see Patent Reference 6).

A metering and mixing device for a viscous material such as ink has plural gear pumps for conveying viscous materials, such as ink, of different types to a mixing section, plural pulse motors (stepping motors) for driving each gear pump, and a drive control device for synchronously driving each pulse motor with a pulse having individual frequency dividing rate corresponding to a mixture ratio of the respective viscous materials such as ink (e.g., see Patent Reference 7).

A gear pump has a pair of fluid transferring gear that rotates in a casing as meshed with each other, and a power transmission gear that is provided at the rotational shaft of the fluid transferring gear at the outside of the casing for synchronously rotating the fluid transferring gear (e.g., see Patent Reference 8).

An intermittent coating device for hot-melt adhesive accepts a hot-melt adhesive transferred from a hot-melt adhesive supplying device, and ejects the accepted adhesive from a hot-melt ejecting module via a gear pump for metering, thereby intermittently coating the hot-melt adhesive on a subject to be coated (e.g., see Patent Reference 9).

A fluid replenishing device for supplying fluid to two faces that relatively move in a gap direction is arranged. In a fluid discharge method, the continuous flow replenished from the fluid replenishing device is converted into an intermittent flow by utilizing pressure change due to the variation in the gap between relative moving faces, and the intermittent discharge amount per 1 dot is adjusted by the number of rotation of the fluid replenishing device (e.g., see Patent Reference 10).

Further, an epoxy applying device controls an application amount of epoxy in a pellet-mounting to a lead frame (e.g., see Patent Reference 11).

A gear pump has an internal suction path positioned at the side where teeth are gradually apart from each other and a tank in which working fluid is present, both of which are coupled via a returning path without passing through a suction port. The working fluid can be sent into the internal suction path through this returning path (e.g., see Patent Reference 12).

There is disclosed a pushing method for a rubber mixture and other elastomers using a gear pump. In a device for pushing out a rubber mixture using a gear pump that is configured such that each of two gears has one insertion port and one common pushing opening arranged in one casing, air and/or gas is vented with air vent, gas bent or vacuuming at the rear of the insertion port on the way of the transport of the mixture to the place where both gears mesh with each other (e.g., see Patent Reference 13).

[Patent Reference 1]

Japanese Unexamined Patent Publication No. 2002-239433 (FIG. 3)

[Patent Reference 2]

Japanese Unexamined Patent Publication No. HEI 11(1999)-43196 (FIG. 1)

[Patent Reference 3]

Japanese Unexamined Patent Publication No. HEI 8(1996)-114193 (FIG. 1)

[Patent Reference 4]

Japanese Unexamined Patent Publication No. 2004-154741 (FIG. 1)

[Patent Reference 5]

Japanese Unexamined Patent Publication No. 2003-245596 (FIG. 1)

[Patent Reference 6]

Japanese Unexamined Patent Publication No. HEI 9(1997)-60595 (FIG. 1)

[Patent Reference 7]

Japanese Unexamined Patent Publication No. HEI 7(1995)-112800 (FIG. 1)

[Patent Reference 8]

Japanese Unexamined Patent Publication No. 2000-9053 (FIG. 1)

[Patent Reference 9]

Japanese Unexamined Patent Publication No. HEI 8(1996)-57385 (FIG. 1)

[Patent Reference 10]

Japanese Unexamined Patent Publication No. 2004-141866 (FIG. 1)

[Patent Reference 11]

U.S. Pat. No. 6,719,550 (the fourth column)

[Patent Reference 12]

Japanese Unexamined Patent Publication No. 2001-342971 (FIG. 1)

[Patent Reference 13]

Japanese Unexamined Patent Publication No. HEI 10(1998)-52852 (FIG. 1)

### SUMMARY OF THE INVENTION

In pellet-mounting in an assembly of a semiconductor device, an adhesive is applied on a plate-like member such as a lead frame or wiring board with a fixed quantity, and then, a semiconductor chip is arranged thereon and pressedly bonded thereto. At this time, the adhesive is supplied mainly by a pump.

An air pump of the pumps for supplying the adhesive has a problem that it is difficult to keep a high-precise discharge performance and to secure low cost and efficient parts cleaning.

A paste such as an adhesive supplied from a pump is supplied to an applied section via a tube, so that the paste is started to be supplied or the supply of the paste is stopped, with a time difference from start timing or stop timing of the pump.

Accordingly, there arises a problem that it is extremely difficult to perform a control of the supplying amount of the paste in a short period.

The Patent Reference 1 (Japanese Unexamined Patent Publication No. 2002-239433) discloses the paste applying device using a gear pump, a method for adjusting the discharge amount by the number of rotation of the gear pump, and a method for applying a paste by directly coupling a syringe and a gear pump and directly coupling a nozzle and a gear pump, but does not disclose how to configure the gear pump to control a trace amount of paste.

The Patent Reference 2 (Japanese Unexamined Patent Publication No. HEI 11(1999)-43196) and Patent Reference 3 (Japanese Unexamined Patent Publication No. HEI 8(1996)-114193) disclose that a viscous fluid is discharged by using a gear pump, but do not disclose how to control the number of rotation of the gear pump for controlling the application of a trace amount of paste.

The Patent Reference 4 (Japanese Unexamined Patent Publication No. 2004-154741) and Patent Reference 5 (Japanese Unexamined Patent Publication No. 2003-245596) disclose a suckback to prevent a spill upon the discharge of the paste, but do not disclose how to control the number of rotation of the gear pump for controlling the application of a trace amount of paste.

The Patent Reference 6 (Japanese Unexamined Patent Publication No. HEI 9(1997)-60595) discloses a use of a gear pump having a structure in which a gap is formed at the tip of the gear pump, but does not disclose a gear pump having a gear structure in which a gear-contact gear and gear-non-contact gear are concentrically provided.

The Patent Reference 7 (Japanese Unexamined Patent Publication No. HEI 7(1995)-112800) discloses that a gear pump is controlled by a pulse motor, but does not disclose a pulse number for a minute control of a rotation number.

The Patent Reference 8 (Japanese Unexamined Patent Publication No. 2000-9053) discloses a known technique wherein a gear pump is driven by a gear synchronized with the shaft of the gear at the outside of the gear pump, but does not disclose that a non-contact gear pump is driven by a non-contact gear, in which the tip end of the gear pump is a non-contact type, at a contact-gear concentrically formed with the non-contact gear.

The Patent Reference 9 (Japanese Unexamined Patent Publication No. HEI 8(1996)-57385) discloses, in a device for metering and applying a hot-melt adhesive by a gear pump, a method for accumulating the hot-melt adhesive by using an accumulator, but does not disclose a method for discharging a trace amount.

The Patent Reference 10 (Japanese Unexamined Patent Publication No. 2004-141866) discloses in FIG. 22 an intermittent discharge of fluid using a gear pump, but does not disclose how to control the gear pump to discharge a trace amount.

The Patent Reference 11 (U.S. Pat. No. 6,719,550) discloses at its fourth column, lines 17 to 22 that a gear pump may be used for controlling an application amount of epoxy by an epoxy applying device for a pellet-mounting to a lead frame, but does not disclose how to control the gear pump for application.

The Patent Reference 12 (Japanese Unexamined Patent Publication No. 2001-342971) discloses a returning path communicating with an internal suction path is provided at an oil seal to directly flow the fluid into the inside from the returning path and air is vented from a vent port when the fluid flows in. Further, the Patent Reference 13 (Japanese Unexamined Patent Publication No. HEI 10(1998)-52852) discloses a gas vent path communicating with the outside is provided at the casing to vent air to the outside.

However, the Patent References 12 and 13 do not have a disclosure in which air is vent from the inside of the gear pump toward the inflow port through the returning path.

Any one of the plural known techniques does not disclose a pulse control in which a gear is minutely rotated in a gear pump. Further, it does not have a disclosure about a gear pump provided with gears concentrically formed, one of which is a contact gear and the other of which is a non-contact gear.

An object of the present invention is to provide a technique for reducing a manufacturing cost.

Another object of the present invention is to provide a technique for miniaturizing a manufacturing device.

The above and other objects and novel features of the present invention will become apparent from the description of the present specification and the accompanying drawings.

A brief description will be given to the outline of the representative aspects of the present invention disclosed in the present application.

The present invention uses a gear structure wherein a non-contact gear and contact gear are concentrically and integrally formed, whereby driving force is given to the contact gear to rotate the non-contact gear, resulting in that the non-contact gear is used as a gear pump for applying a paste.

Further, the present invention provides a manufacturing method of a semiconductor device that applies a paste by using a gear pump having a non-contact gear, wherein the gear pump is pulse-driven by a stepping motor, wherein the rotation control is carried out by the drive having a pulse number of 3000 pulses per one rotation or more for applying the paste.

The present invention has a step of applying a paste on plural device regions formed on a plate-like member by using a gear structure having a non-contact gear and a contact gear concentrically and integrally formed, wherein driving force is given to the contact gear to rotate the non-contact gear for causing the non-contact gear to be used as a gear pump; a step of bonding a semiconductor chip to the plural device regions via the paste; a step of forming an integral seal member by performing a resin encapsulation with the plural device regions covered with one cavity of a resinous molding die; and a step of cutting the seal member into individual devices.

The present invention applies a paste by using a gear pump having a non-contact gear, wherein the gear pump is pulse-driven by a stepping motor, wherein the rotation control is carried out by the drive having a pulse number of 3000 pulses per one rotation or more for applying the paste.

A semiconductor manufacturing device according to the present invention uses a gear structure wherein a non-contact gear and contact gear are concentrically and integrally formed, whereby driving force is given to the contact gear to rotate the non-contact gear, resulting in that the non-contact gear is used as a gear pump for applying a paste.

The present invention provides a semiconductor manufacturing method comprising the steps of: (a) applying a paste on plural device regions formed on a plate-like member by using a gear structure having a non-contact gear and a contact gear that are concentrically and integrally formed with each other, and giving driving force to the contact gear to rotate the non-contact gear, thereby causing the non-contact gear to be used as a gear pump; (b) bonding a semiconductor chip via the paste at the plural device regions; (c) forming an integral seal member by performing a resin encapsulation with the plural device regions covered with one cavity of a resinous molding die; and (d) cutting the integral seal member into individual devices.

In the above-mentioned semiconductor manufacturing method, the application amount of the paste is 0.01 to 0.5 ml per one application.

In the above-mentioned semiconductor manufacturing method, the application speed of the paste is 0.3 to 0.5 sec per one application.

In the above-mentioned semiconductor manufacturing method, the gear pump has a housing for accommodating the non-contact gear and the contact gear, and a part of the housing is made of a transparent plate.

In the above-mentioned semiconductor manufacturing method, the gear pump has a housing for accommodating the non-contact gear and the contact gear, and the housing is assembled so as to be dividable into three.

In the above-mentioned semiconductor manufacturing method, the gear pump is pulse-driven by a stepping motor, and the gear pump is controlled to be rotated by a drive with a pulse number of 3000 pulses or more per one rotation for applying the paste.

The above-mentioned semiconductor manufacturing method includes a step of venting air in the pump toward the outside by rotating the non-contact gear, before the step (a).

The present invention provides a semiconductor manufacturing device for applying a paste by using a gear pump having a non-contact gear, wherein the gear pump is pulse-driven by a stepping motor, and the gear pump is controlled to be rotated by a drive with a pulse number of 3000 pulses or more per one rotation for applying the paste.

In the above-mentioned semiconductor manufacturing device, the application amount of the paste is 0.01 to 0.5 ml per one application.

In the above-mentioned semiconductor manufacturing device, the application speed of the paste is 0.3 to 0.5 sec per one application.

In the above-mentioned semiconductor manufacturing device, the gear pump has a housing for accommodating the non-contact gear, and a part of the housing is made of a transparent plate.

In the above-mentioned semiconductor manufacturing device, the gear pump has a housing for accommodating the non-contact gear, and the housing is assembled so as to be dividable into three.

In the above-mentioned semiconductor manufacturing device, driving force is given to the non-contact gear by a contact gear that is concentrically and integrally formed with the non-contact gear.

In the above-mentioned semiconductor manufacturing device, the gear pump has a housing for accommodating the non-contact gear, wherein a syringe for accommodating the paste and the housing as well as a nozzle for discharging the paste and the housing are directly coupled to each other.

In the above-mentioned semiconductor manufacturing device, a low thermal conductive member is interposed at the connecting section between the stepping motor and the shaft of the gear pump.

In the above-mentioned semiconductor manufacturing device, the gear pump has a housing for accommodating the non-contact gear, and a groove section is formed at the inner wall of the housing for venting air in the gear pump to the outside by the rotation of the non-contact gear.

The present invention provides a semiconductor manufacturing device wherein a gear structure having a non-contact gear and contact gear that are concentrically and integrally formed is used, whereby driving force is given to the contact gear to rotate the non-contact gear, thereby applying a paste with the non-contact gear used as a gear pump.

In the above-mentioned semiconductor manufacturing device, the application amount of the paste is 0.01 to 0.5 ml per one application.

In the above-mentioned semiconductor manufacturing device, the application speed of the paste is 0.3 to 0.5 sec per one application.

In the above-mentioned semiconductor manufacturing device, the gear pump has a housing for accommodating the non-contact gear and the contact gear, and a part of the housing is made of a transparent plate.

In the above-mentioned semiconductor manufacturing device, the gear pump has a housing for accommodating the non-contact gear and the contact gear, and the housing is assembled so as to be dividable into three.

In the above-mentioned semiconductor manufacturing device, the gear pump is pulse-driven by a stepping motor, and the gear pump is controlled to be rotated by a drive with a pulse number of 3000 pulses or more per one rotation for applying the paste.

In the above-mentioned semiconductor manufacturing device, the gear pump has a housing for accommodating the non-contact gear and the contact gear, wherein a syringe for accommodating the paste and the housing as well as a nozzle for discharging the paste and the housing are directly coupled to each other.

In the above-mentioned semiconductor manufacturing device, a low thermal conductive member is interposed at the connecting section between the stepping motor and the shaft of the gear pump.

In the above-mentioned semiconductor manufacturing device, the gear pump has a housing for accommodating the non-contact gear and the contact gear, and a groove section is formed at the inner wall of the housing for venting air in the gear pump to the outside by the rotation of the non-contact gear.

### EFFECT OF THE INVENTION

A brief description will be given to the effects obtained by the representative aspects of the present invention disclosed in the present application.

The non-contact gear and the contact gear are processed so as to be concentric and integral, thereby being capable of reducing cost taken for the manufacture and assembly, such as the reduction in manufacturing setup time of the gear or elimination of assembling adjustment time. As a result, manufacturing cost can be reduced. Further, the gear pump has less number of components, so that reduction in cost and miniaturization can be achieved. According to this, the cost for the semiconductor manufacturing device to which the gear pump is incorporated can be reduced, and further, the mounting space of the gear pump can be decreased, thereby being capable of miniaturizing the semiconductor manufacturing device.

### BRIEF DESCRIPTION OF THE DRAWINGS

FIG. 1 is a sectional view showing one example of a structure of a gear pump used for assembling a semiconductor device according to an embodiment of the present invention;

FIG. 2 is a back side view showing the structure of the gear pump shown in FIG. 1;

FIG. 3 is a perspective view and partial enlarged view respectively showing a gear structure incorporated in the gear pump shown in FIG. 1 and a tooth profile;

FIG. 4 is a sectional view showing one example of a structure of a pump system provided with the gear pump shown in FIG. 1;

FIG. 5 is a sectional view showing one example of a structure of a semiconductor manufacturing device having incorporated therein the pump system shown in FIG. 4 and a state of an applied paste;

FIG. 6 is a plan view showing one example of a state in which the paste shown in FIG. 5 is applied on a frame;

FIG. 7 is a graph of a paste discharge amount showing one example of a pump performance of the pump system shown in FIG. 4;

FIG. 8 is a conceptual view showing a structure of a modified example of the pump system according to the embodiment of the present invention;

FIG. 9 is a conceptual view showing a structure of a modified example of the pump system according to the embodiment of the present invention;

FIG. 10 is a sectional view showing a structure of a modified example of a gear pump according to the embodiment of the present invention;

FIG. 11 is a sectional view showing a structure of a syringe connecting section and nozzle connecting section of the gear pump according to the modified example shown in FIG. 10;

FIG. 12 a sequence flowchart showing one example of a sequence of an operation for applying a paste in the semiconductor manufacturing device according to the embodiment of the present invention;

FIG. 13 is a perspective view showing one example of a structure of a semiconductor device assembled in accordance with the manufacturing method of a semiconductor device according to the embodiment of the present invention;

FIG. 14 is a sectional view showing one example of the structure of the semiconductor device shown in FIG. 13;

FIG. 15 is a sectional view showing one example of the structure of the semiconductor device during assembling after a pellet is mounted according to the embodiment of the present invention;

FIG. 16 is a sectional view showing one example of the structure of the semiconductor device during assembling after a wire bonding according to the embodiment of the present invention;

FIG. 17 is a sectional view showing one example of the structure of the semiconductor device upon a resin encapsulation according to the embodiment of the present invention;

FIG. 18 is a sectional view showing one example of the structure of the semiconductor device during assembling after the resin encapsulation according to the embodiment of the present invention;

FIG. 19 is a sectional view showing one example of the structure of the semiconductor device during assembling after a soldering bump is mounted according to the embodiment of the present invention; and

FIG. 20 is a sectional view showing the structure of the semiconductor device upon dicing into individual devices according to the embodiment of the present invention.

### DETAILED DESCRIPTION OF THE PREFERRED EMBODIMENTS

In the following embodiments, explanations of the same or similar portions will not be repeated in principle except when particularly required.

In the following embodiments, descriptions will be made separately to plural sections or embodiments when required. Unless otherwise stated, they are not independent of each other, and one is dependent partially or wholly on others in terms of variants, details, additional descriptions, and the like.

In the embodiments below, the number of elements (including count, numeric value, quantity, and range), when designated, are not limited to the designated number and may be around the designated number, except in cases where it is explicitly specified and cases where it is theoretically limited to the specific number.

The present invention will be explained in detail with reference to drawings. In all drawings for explaining the embodiments, elements having identical functions are identified by the same reference numerals and duplicate descriptions of them are omitted.

### EMBODIMENT

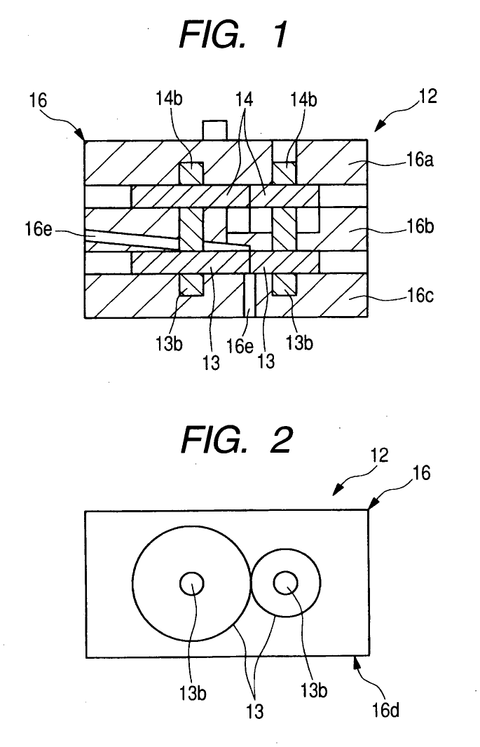

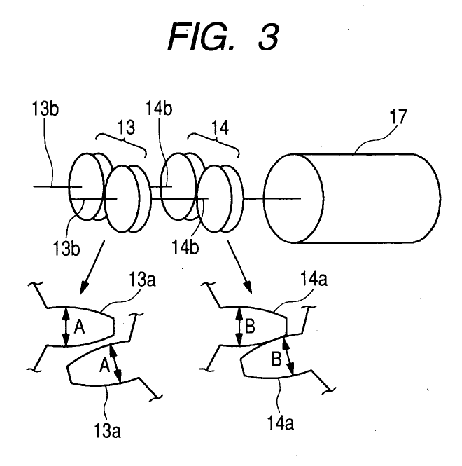

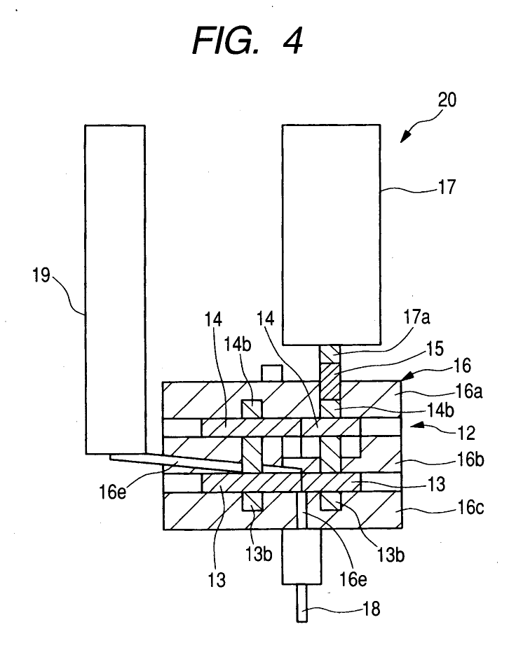

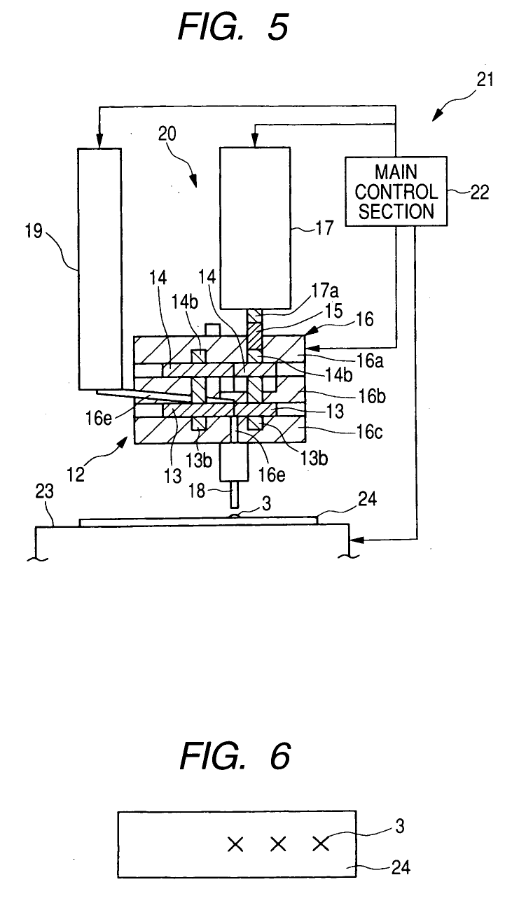

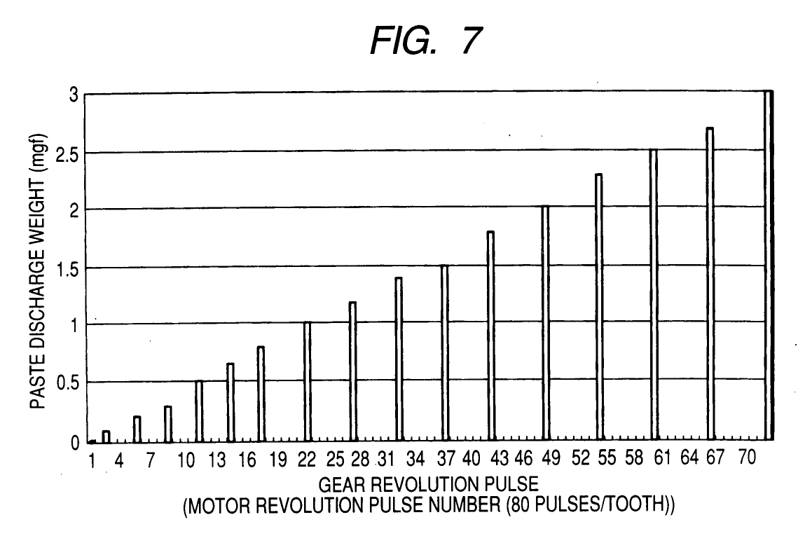

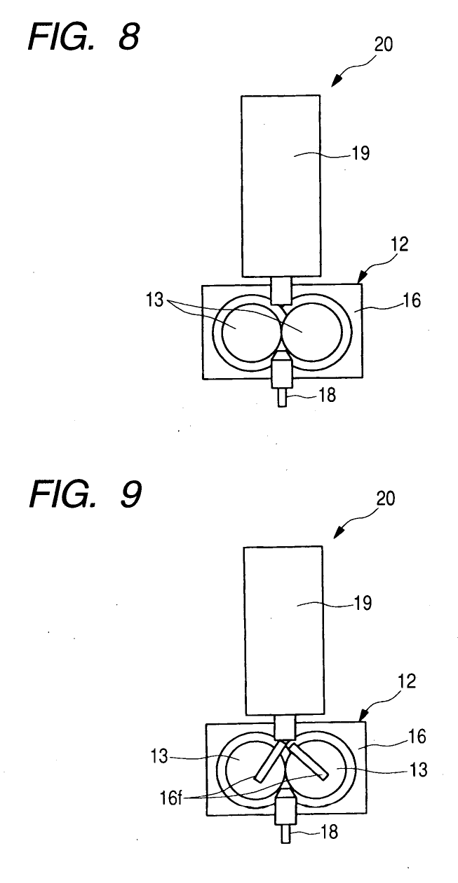

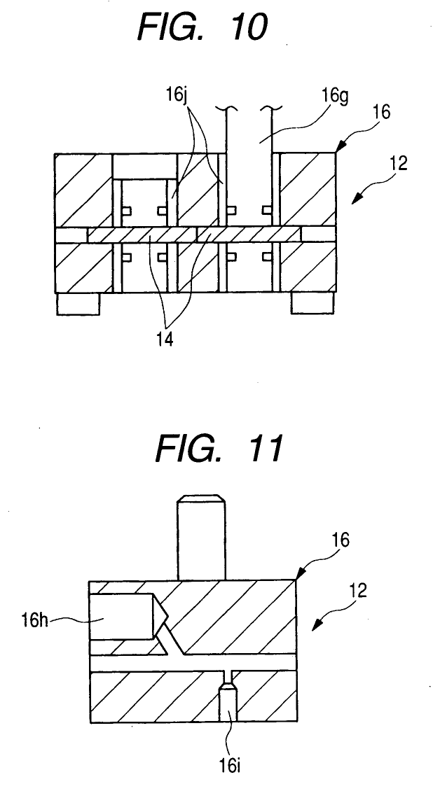

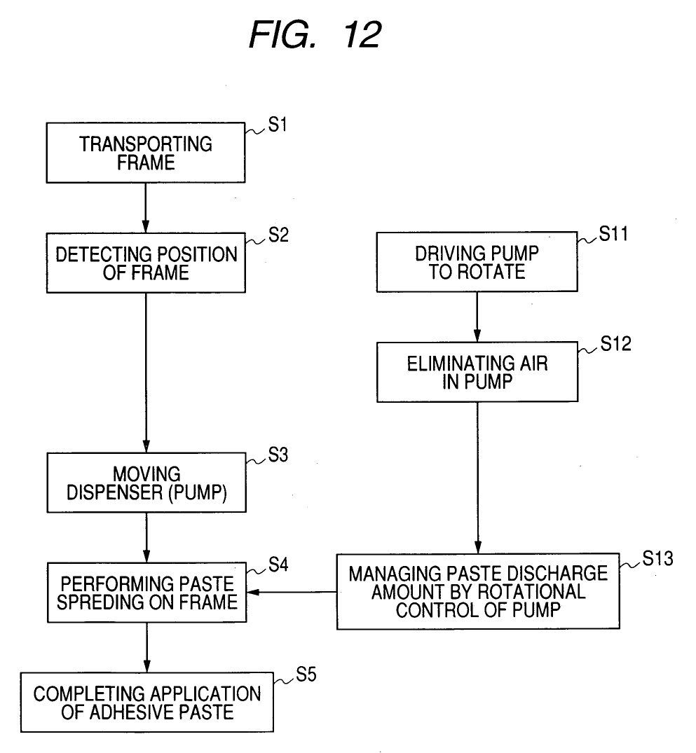

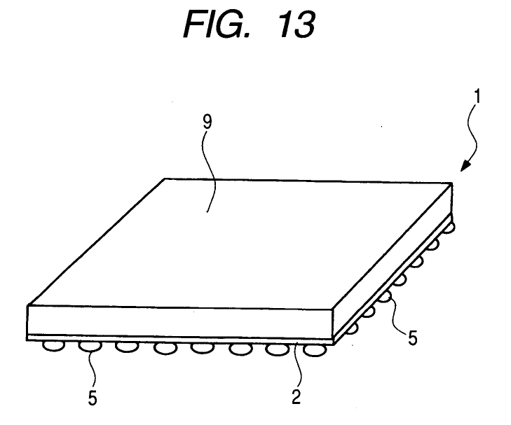

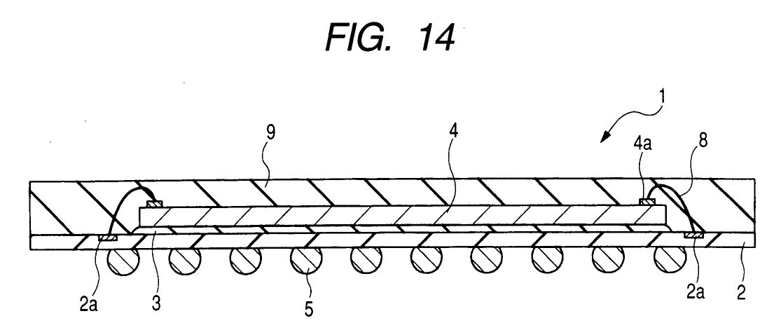

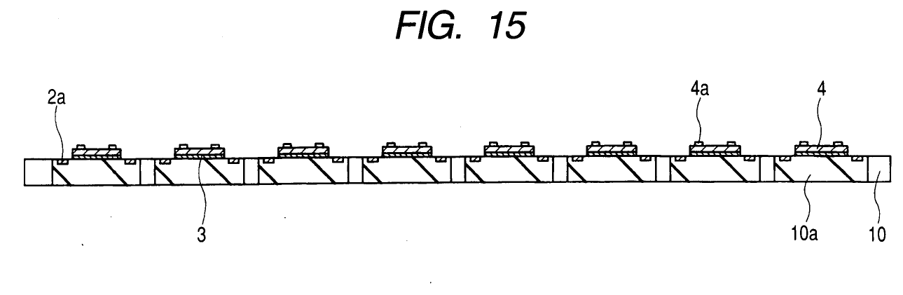

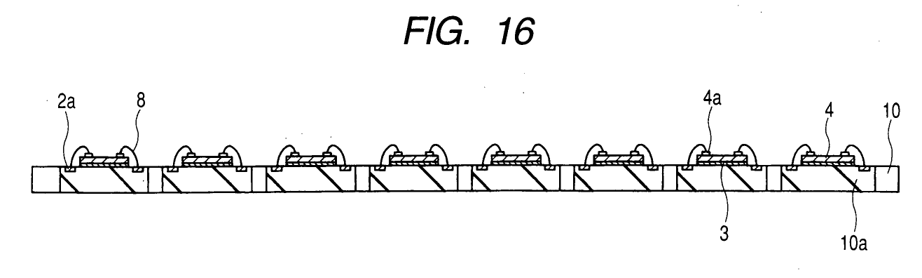

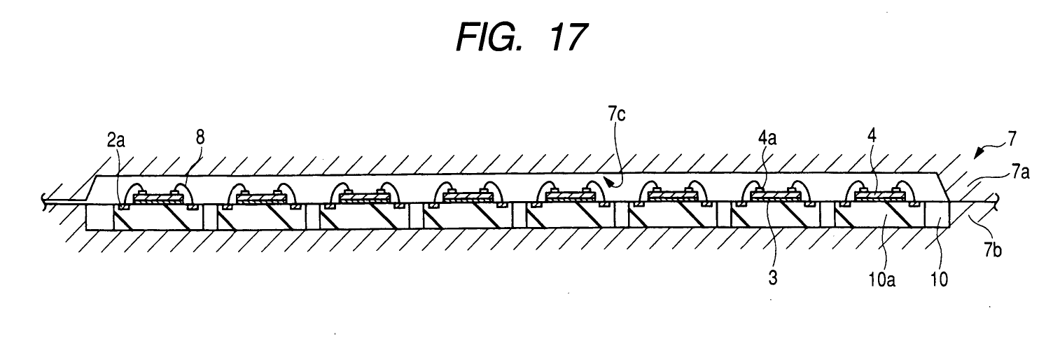

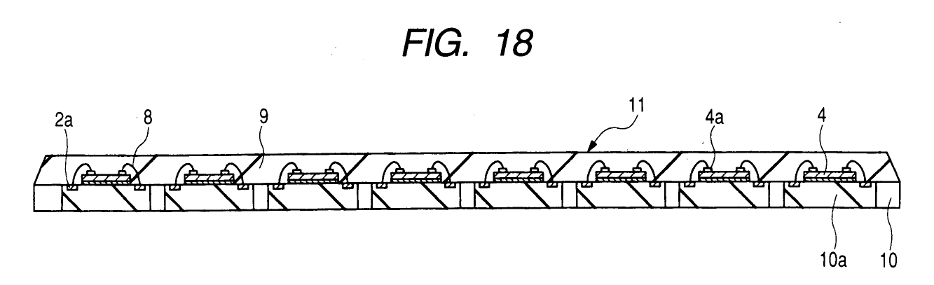

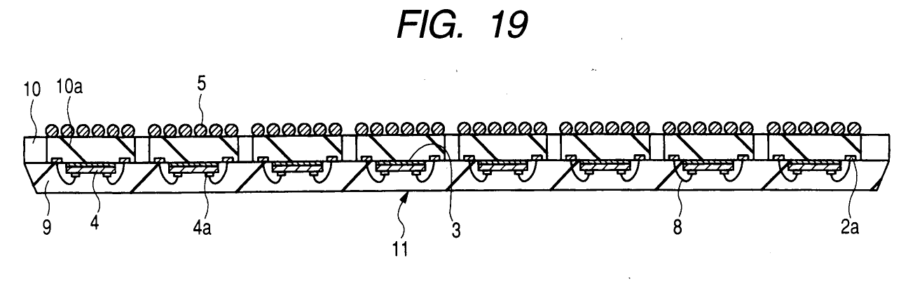

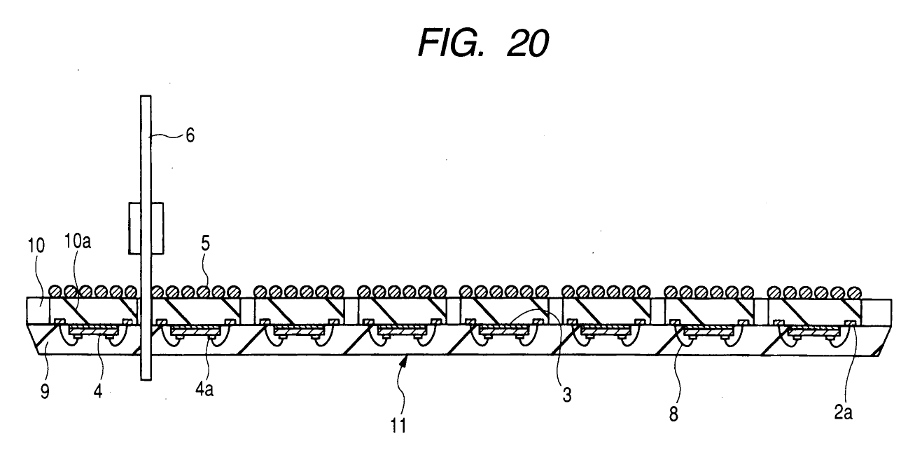

FIG. 1 is a sectional view showing one example of a structure of a gear pump used for assembling a semiconductor device according to the embodiment of the present invention; FIG. 2 is a back side view showing the structure of the gear pump shown in FIG. 1; FIG. 3 is a perspective view and partial enlarged view respectively showing a gear structure incorporated in the gear pump shown in FIG. 1 and a tooth profile; FIG. 4 is a sectional view showing one example of a structure of a pump system provided with the gear pump shown in FIG. 1; FIG. 5 is a sectional view showing one example of a structure of a semiconductor manufacturing device having incorporated therein the pump system shown in FIG. 4 and a state of an applied paste; FIG. 6 is a plan view showing one example of a state in which the paste shown in FIG. 5 is applied on a frame; FIG. 7 is a graph of a paste discharge amount showing one example of a pump performance of the pump system shown in FIG. 4; FIG. 8 and FIG. 9 are conceptual views showing structures of modified examples of the pump system according to the embodiment of the present invention; FIG. 10 is a sectional view showing a structure of a modified example of a gear pump according to the embodiment of the present invention; FIG. 11 is a sectional view showing a structure of a syringe connecting section and nozzle connecting section of the gear pump according to the modified example shown in FIG. 10; FIG. 12 a sequence flowchart showing one example of a sequence of an operation for applying a paste in the semiconductor manufacturing device according to the embodiment of the present invention; FIG. 13 is a perspective view showing one example of a structure of a semiconductor device assembled in accordance with the manufacturing method of a semiconductor device according to the embodiment of the present invention; FIG. 14 is a sectional view showing one example of the structure of the semiconductor device shown in FIG. 13; FIG. 15 is a sectional view showing one example of the structure of the semiconductor device during assembling after a pellet is mounted according to the embodiment of the present invention; FIG. 16 is a sectional view showing one example of the structure of the semiconductor device during assembling after a wire bonding according to the embodiment of the present invention; FIG. 17 is a sectional view showing one example of the structure of the semiconductor device upon a resin encapsulation according to the embodiment of the present invention; FIG. 18 is a sectional view showing one example of the structure of the semiconductor device during assembling after the resin encapsulation according to the embodiment of the present invention; FIG. 19 is a sectional view showing one example of the structure of the semiconductor device during assembling after a soldering bump is mounted according to the embodiment of the present invention; and FIG. 20 is a sectional view showing the structure of the semiconductor device upon dicing into individual devices according to the embodiment of the present invention.

The manufacturing method of a semiconductor device according to the embodiment relates mainly to an application of a paste 3 that is an adhesive for bonding a semiconductor chip 4 in a pellet-mounting process shown in FIG. 14, wherein the application of the paste 3 is carried out by using a gear pump 12 shown in FIG. 1.

The structure of the gear pump 12 shown in FIG. 1 will be explained. The gear pump 12 has a gear structure including a non-contact gear 13 and a contact gear 14 that are concentrically and integrally formed. By using the gear structure, driving force is given to the contact gear 14 to rotate the non-contact gear, whereby the non-contact gear 13 is used as the gear pump 12 to discharge the paste 3.

In this embodiment, the non-contact gear 13 serves as a pump gear 13, while the contact gear 14 serves as a driving gear 14 as shown in FIG. 3. Specifically, a rotational shaft 13b of the pump gear 13 and a rotational shaft 14b of the driving gear 14 are concentrically formed, and the pump gear 13 and the driving gear 14 are integrally formed. With this structure, when driving force is given to the driving gear 14, the driving gear 14 gives driving force to the pump gear 13 that is formed so as to be concentric and integral with the driving gear 14, so that the pump gear 13 rotates.

The center phase of the teeth of the pump gear 13 and that of the driving gear 14 agree with each other. Further, the width (B) of the tooth 14a of the driving gear 14 is formed to be greater than the width (A) of the tooth 13a of the pump gear 13 as shown in FIG. 3 (A<B). Accordingly, the pump gear 13 rotates with gears non-contact to each other.

It should be noted that the size of the pump gear 13 and the size of the driving gear 14 are not more than module 1, preferably module 0.3, for example.

The pump gear 13 and the driving gear 14 are rotatably housed in a housing 16 that can be divided into three corresponding to the discharge direction of the paste 3. Specifically, the housing 16 of the gear pump 12 is composed of a first housing section 16a, second housing section 16b and third housing section 16c in the discharge direction as shown in FIG. 1.

Paste paths 16e are formed at both sides with respect to the pump gear 13 of the housing 16 of the gear pump 12. The paste path 16e open to the side face of the gear pump 12 is a path at the intake side, while the paste path 16e open to the back face is a path at the discharge side. The paste path 16e at the intake side and the paste path 16e at the discharge side communicate with each other with the pump gear 13 interposed between both paths. The paste 3 supplied from the paste path 16e at the intake side is sent to the paste path 16e at the discharge side due to the rotation of the pump gear 13, and then, discharged to the outside.

The housing 16 composed of the first housing section 16a, second housing section 16b and third housing section 16c is made of a transparent plate 16d such as, for example, acryl, polyvinyl chloride, polycarbonate, or the like, so that the fluid state of the paste 3 accommodated therein can be visually confirmed from the backside surface of the gear pump 12.

Subsequently, a pump system shown in FIG. 4 will be explained. A pump system 20 shown in FIG. 4 has such a structure that a stepping motor 17 that exerts driving force on the driving gear 14, a nozzle 18 that ejects the paste 3, and a syringe 19 that is a container accommodating the paste 3 are attached to the gear pump 12 shown in FIG. 1. The nozzle 18 is directly coupled to the housing 16 so as to communicate with the paste path 16e at the discharge side, while the syringe 19 is directly coupled to be mounted on the gear pump 12 so as to communicate with the paste path 16e at the intake side.

The stepping motor 17 has a rotational shaft 17a that is coupled to the rotational shaft 14b of the driving gear 14 via a low thermal conductive member 15. Specifically, the low thermal conductive member 15 such as, for example, ceramics, plastics, rubbers, or the like is interposed at the joint section of the stepping motor 17 and the rotational shaft 14b of the driving gear 14 at the gear pump 12.

A servomotor may be used instead of the stepping motor 17.

In the pump system 20 shown in FIG. 4, driving force is exerted on the driving gear 14 by the stepping motor 17, whereby the pump gear 13 is rotated by the driving force given by the driving gear 14, and the paste 3 supplied from the syringe 19 is dripped via the nozzle 18 for application with the rotation of the pump gear 13 serving as a pump.

In the pump system 20, the gear pump 12 is pulse-driven by the stepping motor 17. For example, the rotation is controlled by drive of not less than 3000 pulses per rotation, preferably 5000 pulses per rotation, thereby applying the paste 3. Accordingly, the pump system 20 can apply a trace amount of paste 3 by performing a pulse control so as to minutely rotate the gears in the gear pump 12.

The application amount of the paste 3 in the pump system 20 is, for example, 0.01 to 0.5 ml per one application, and the application speed of the paste 3 is 0.3 to 0.5 sec per one application.

Subsequently, a pump performance of the pump system 20 will be explained with reference to FIG. 7. FIG. 7 shows data of the discharge amount of the paste 3 when the pump is rotated, i.e., shows a discharge weight (axis of ordinate) of the paste 3 to the revolution of the gear pump 12 (axis of abscissa). It can be understood that the discharge amount of a minimum of 0.01 ml can be secured according to the minimum revolution angle of the gear pump 12.

Subsequently, a semiconductor manufacturing device 21 shown in FIG. 5 according to the embodiment will be explained.

A semiconductor manufacturing device 21 shown in FIG. 5 has the pump system 20 shown in FIG. 4, a main control section 22 that controls the pump system 20, and a stage 23 that can hold a plate-like member such as a lead frame 24 or multi-chip bonded substrate 10 shown in FIG. 15. The semiconductor device manufacturing device 21 has a function for applying the paste 3 on at least the plate-like member upon bonding a semiconductor chip 4 to the plate-like member by a pellet-mounting process (sometimes referred to as die bonding process) in the assembly of a semiconductor device.

Accordingly, in the semiconductor manufacturing device 21, at the pellet-mounting process, the plate-like member such as the lead frame 24 (the multi-chip bonded substrate 10 may be possible) is arranged on the stage 23, and then, the main control section 22 controls the pump system 20 to perform a pulse control for minutely rotating the gear of the gear pump 12, thereby applying a trace amount of paste 3 on the lead frame 24. For example, the paste 3 is applied on plural sections on the lead frame 24 as shown in FIG. 6.

Thereafter, the semiconductor chip 4 is arranged and bonded to the lead frame 24 via the paste 3.

Subsequently, a pump system 20 according to the modified example shown in FIG. 8 and FIG. 9 will be explained.

The pump system 20 shown in FIG. 8 according to the modified example has the pump gear 13 that is vertically mounted. The pump performance is the same as that of the pump system 20 shown in FIG. 4. The pump system 20 in which the pump gear 13 is vertically mounted may be adopted depending upon the condition of the free space around the gear pump 12.

The pump system 20 shown in FIG. 9 according to the modified example is configured such that, in the system shown in FIG. 8 having the pump gear 13 vertically mounted, a groove section 16f for venting air in the gear pump 12 to the outside due to the rotation of the pump gear 13 is formed at the inner wall of the housing 16.

With this configuration, the air present in the narrow gap between the pump gear 13 and the housing 16 is pushed out toward the pump intake side by the paste 3, that comes into the gap due to the pump pressure, and by the rotation of the pump gear 13, sucked from the intake side of the groove section 16f and consequently vented to the discharge side (nozzle side).

Therefore, the pump gear 13 is rotated to vent the air in the gear pump 12 by using the pump system 20 shown in FIG. 9 before the process for applying the paste 3, whereby air present from the beginning in the pump or air present in the paste can be eliminated from the gear pump 12.

Subsequently, the gear pump 12 shown in FIG. 10 according to the modified example will be explained.

The gear pump 12 shown in FIG. 10 according to the modified example is a gear pump 12 having only the contact gear. Specifically, the driving gear 14 that is the contact gear also has the pump function, and the gear pump 12 is provided with only a pair of gears in the housing 16. A shaft bearing 16j is provided at the accommodating section of the gear shaft in the housing 16. Further, a motor connecting section 16g is provided at the motor mounting section. Moreover, the housing 16 has provided thereto a syringe connecting section 16h and nozzle connecting section 16i as shown in FIG. 11, whereby the driving motor, and syringe 19 and the nozzle 18 shown in FIG. 9 can directly coupled to the housing 16.

This allows the miniaturization of the gear pump 12. In this case too, the gear pump 12 is pulse-driven by the stepping motor. For example, the rotation is controlled by drive of not less than 3000 pulses per rotation, preferably 5000 pulses per rotation, thereby applying the paste 3. Accordingly, the pump system 20 can apply a trace amount of paste 3 by performing a pulse control so as to minutely rotate the gears in the gear pump 12.

Subsequently, an operation sequence of applying the paste by the semiconductor manufacturing device 21 shown in FIG. 5 will be explained with reference to the sequence flowchart shown in FIG. 12.

Here, the gear pump 12 of the pump system 20 mounted to the semiconductor manufacturing device 21 has the groove section 16f shown in FIG. 9 for eliminating air provided at the housing 16, and the following explanation is made by taking as one example the case wherein the plate-like member on which the paste 3 is to be applied is the lead frame 24 (the multi-chip bonded substrate 10 may be possible).

Firstly, a certain lead frame 24 is transported at a step S1 of frame transport shown in FIG. 12, so that the lead frame 24 is placed on a predetermined position on the stage 23, where the position of the lead frame 24 is detected by performing the frame position detection shown at a step S2.

On the other hand, before the paste 3 is applied on the predetermined position on the lead frame 24, the pump rotation drive shown at a step S11 is carried out to vent air in the gear pump 12 via the groove section 16f at the housing 16. Specifically, the elimination of air in the pump shown at a step S12 is performed.

Thereafter, the dispenser (pump system 20) is moved shown at a step S3, whereby the gear pump 12 is moved to the predetermined position on the lead frame 24.

Then, the management of the paste discharge amount by the rotation control of the pump shown at a step S13 is carried out to rotate the gear pump 12 at a predetermined angle and move the nozzle 18, that operates so as to be integral with the gear pump 12, with a predetermined locus, whereby the paste 3 is applied on the lead frame 24 (step S4).

After the application of the paste, the gear pump 12 is reversely rotated with a predetermined amount for collecting only a little amount of paste 3 remaining at the tip end of the nozzle 18 into the gear pump 12. Then, the application of the paste 3 (adhesive agent) on the lead frame 24 with a predetermined amount is completed (step S5).

According to the operation sequence for applying the paste, air in the gear pump 12 is eliminated before the paste 3 is applied, thereby being capable of reducing the dispersion in the discharge amount of the paste 3. Further, the gear pump 12 is reversely rotated after the paste is dripped, thereby being capable of preventing the fall of the paste 3 that is about to eject from the tip end of the nozzle 18 or the fall of the paste 3 that is by any chance discharged after the pump is stopped. Accordingly, the contamination of the lead frame 24 due to the fall of the paste 3 as described above can be prevented.

Subsequently explained specifically are a manufacturing method of the semiconductor device according to the embodiment and effects obtained from the semiconductor manufacturing device.

The pump gear 13 and the driving gear 14 in the gear pump 12 are formed so as to be concentric and integral with each other. Further, the center phase of the teeth of the pump gear 13 and that of the driving gear 14 agree with each other. Further, the width (B) of the tooth 14a of the driving gear 14 is formed to be greater than the width (A) of the tooth 13a of the pump gear 13 as shown in FIG. 3 (A<B). Accordingly, the pump gear 13 rotates with gears non-contact to each other.

Therefore, the friction generated between the tooth surfaces of the pump can be avoided, thereby being capable of preventing that the paste 3, which is easy to be coagulated due to a temperature rise, does not flow in the gear pump 12 due to the increased viscosity.

The pump gear 13 and the driving gear 14 are processed so as to be concentric and integral, thereby being capable of reducing cost taken for the manufacture and assembly, such as the reduction in manufacturing setup time of the gear or elimination of assembling adjustment time. As a result, manufacturing cost can be reduced.

The gear pump 12 has less number of components, so that reduction in cost and miniaturization can be achieved. According to this, the cost for the semiconductor manufacturing device to which the gear pump 12 is incorporated can be reduced, and further, the mounting space of the gear pump 12 can be decreased, thereby being capable of miniaturizing the semiconductor manufacturing device 21.

The assembling adjustment of the gear pump 12 is simple, so that the maintenance performance of the gear pump 12 can be enhanced, and hence, the rate of operation of the semiconductor manufacturing device 21 can be enhanced.

The gear pump 12 using the pump gear 13, which is the non-contact gear, is rotation-controlled by the stepping motor 17 or the servomotor to apply the paste due to the minute rotation, whereby the minimum control amount of the paste discharge can be controlled to be the ultratrace amount. Therefore, the gear pump 12 can also be applied to the assembly of a semiconductor device adopting a miniaturized semiconductor chip 4 (e.g., a chip having a size of 0.5 mm×0.5 mm, or 0.3 mm×0.3 mm). For example, the controlled amount of the paste required for the size-miniaturized and thickness-reduced semiconductor chip 4 is approximately 0.01 ml. The application amount of the paste 3 in the pump system 20 according to this embodiment is 0.01 to 0.5 ml per one application, so that the discharge amount of a minimum of 0.01 ml can be secured. Accordingly, the paste 3 can be supplied to perform pellet-mounting for even the miniaturized semiconductor chip 4 having the chip area of 1 mm×1 mm or less. Specifically, high-precise assembly can be carried out even for the semiconductor chip 4 that is miniaturized as described above.

The application speed of the paste 3 is set to 0.3 to 0.5 sec per one application, whereby the heat generation from the driving source can be reduced. As a result, the heat transmission amount from the driving source into the gear pump 12 can be decreased. Consequently, the paste 3 having a short heat-resistant life can be handled.

The size of the pump gear 13 or driving gear 14 is set to not more than module 1, whereby the control can be carried out even if the discharge amount of the paste 3 is a little. Specifically, decreasing the size of the gear can reduce the discharge amount of the paste 3 per rotational angle of the gear. Accordingly, the minimum control angle of the rotational amount can be reduced, thereby being capable of realizing a discharge pump discharging a trace amount of paste due to the gear pump 12.

The housing 16 of the gear pump 12 can be divided into three sections. Therefore, even if there arises a problem in which the paste 3 is about to be solidified in the gear pump 12 and not discharged, the necessary part of the housing is removed for maintenance, and then, this housing part is again attached to complete the maintenance. Accordingly, the time for the maintenance or adjustment in the gear pump 12 can be shortened.

At least a part of or whole of the housing 16 of the gear pump 12 is made of the transparent plate 16d, so that the inside of the pump can be observed without disassembling the gear pump 12. Thus, it becomes possible to avoid a surplus operation such as disassembling the gear pump 12 for confirmation due to unnecessary worries.

In the gear pump 12, the nozzle 18 is directly coupled to the housing 16, and the syringe 19 is directly coupled to the gear pump 12, whereby the whole pump system can be miniaturized to have a weight of 1 kg or less. Accordingly, the gear pump can be directly mounted on a nozzle section that is operated with an acceleration of 2G or more, so that it can be mounted without providing a tube or the like from the pump section to the nozzle section. Thus, the rotational drive of the gear pump 12 and the discharge timing of the paste 3 from the tip end of the nozzle 18 can be generally synchronized, thereby being capable of controlling the discharge amount of the paste 3 with high precision.

The low thermal conductive member 15 is interposed between the rotation shaft 17a of the stepping motor 17 serving for driving the gear and the rotation shat 14b of the driving gear 14, so that the transmission of heat generated from the stepping motor 17 can be blocked. With this configuration, an adverse effect to the adhesive reliability of the semiconductor chip 4 bonding can be avoided; such as the paste 3 having a short heat-resistant life becomes highly viscosity in the pump to produce a clog.

The groove section 16f for venting air is formed at the inner wall of the housing 16 of the gear pump 12. Therefore, air coming into the gear pump 12 due to the rotation of the pump gear 13 can be vented to the outside of the gear pump 12 via the intake side, discharge side and nozzle 18, resulting in preventing the occurrence of a problem in which air in the gear pump 12 is compressed due to pump pressure during the pump operation to change the space in the gear pump 12, and the paste 3 that is to be discharged to the outside is accumulated in the gear pump 12.

As a result, the paste 3 can be discharged with high precision according to the discharge capacity of the gear pump 12.

Subsequently explained is an assembly of a semiconductor device using the semiconductor manufacturing device 21 shown in FIG. 5 according to this embodiment, taking the case for assembling a CSP (Chip Scale Package) 1 shown in FIG. 13 as one example.

The CSP 1 is a resin-encapsulated miniaturized semiconductor package having a semiconductor chip 4 mounted on a package substrate 2 as shown in FIG. 14. The CSP 1 is also a BGA (Ball Grid Array) type semiconductor package having plural soldering bumps, which are external terminals, arranged on the back face of the package substrate 2.

The semiconductor chip is fixedly bonded to the package substrate 2 via the paste 3 which is an adhesive applied by using the gear pump 12 in the pump system 20 of the semiconductor manufacturing device 21. The semiconductor chip 4 is made of, for example, a silicon. Plural pads 4a, which are surface electrodes, are provided on its major face. These pads 4a and connection terminals 2a corresponding to each pad 4a on the package substrate 2 are electrically connected via a conductive wire 8.

A seal member 9 for resin-encapsulating the semiconductor chip 4 or plural conductive wires 8 is arranged on the major face of the package substrate 2. It should be noted that the conductive wire 8 is, for example, a gold wire, and the seal member 9 is, for example, thermosetting epoxy resin.

The assembly of the CSP 1 shown in FIGS. 13 and 14 will be explained with reference to FIGS. 15 to 20. In the assembly of the CSP 1 according to this embodiment, a multi-chip bonded substrate 10 shown in FIG. 15 is used as a plate-like member for bonding the semiconductor chip 4, and collectively molding or so called MAP (Mold Array Package) is used for resin encapsulation.

Firstly, the multi-chip bonded substrate 10 shown in FIG. 15 is prepared having plural device regions 10a corresponding to the individual package substrate 2 and dividedly arranged.

Thereafter, pellet-mounting (die bonding) is performed by using the semiconductor manufacturing device 21 shown in FIG. 5, thereby fixedly bonding the semiconductor chip 4 on the multi-chip bonded substrate 10 via the paste 3 which is an adhesive, as shown in FIG. 15.

In the pellet-mounting process, before the paste 3 is applied, the pump gear 13 of the gear pump 12 in the pump system 20 of the semiconductor manufacturing device 21 is firstly rotated to vent air in the gear pump 12 to the outside. Specifically, the groove section 16f shown in FIG. 9 is formed at the inner wall of the housing 16 of the gear pump 12 in the pump system 20. The pump gear 13 is rotated before the paste 3 is applied, whereby the air present in a narrow gap between the pump gear 13 and the housing 16 is pushed and advanced toward the pump intake side by the paste 3 going into the gap due to the pump pressure, and the advanced air is sucked from the sucktion side of the groove section 16f and vented to the discharge side (nozzle side) due to the rotation of the pump gear 13.

As a result, air present in the gear pump 12 from the beginning or air present in the paste can be eliminated from the gear pump 12.

Thereafter, driving force is given to the driving gear 14 of the gear pump 12 in the pump system 20 for rotating the pump gear 13, whereby the paste 3 which is an adhesive is applied on the plural device regions 10a formed on the multi-chip bonded substrate (plate-like member) 10 via the nozzle 18 with the pump gear 13 as a pump.

Then, the back face of the semiconductor chip 4 is bonded to the plural device regions 10a via the paste 3, thereby completing the pellet-mounting.

Thereafter, a wire bonding is performed as shown in FIG. 16, to thereby electrically connect the pad 4a of the semiconductor chip 4 and the connection terminal 2a at the device region 10a on the multi-chip bonded substrate 10 through a conductive wire 8 such as a gold wire.

Then, the resin encapsulation is performed. Here, the resin encapsulation is performed with collectively molding or so called MAP, i.e., Mold Array Package. As shown in FIG. 17, the multi-chip bonded substrate 10 is arranged on a lower molding die 7b of a resinous molding die 7, and then, the plural device regions 10a on the multi-chip bonded substrate 10 are covered with one cavity 7c of an upper molding die 7a of the resinous molding die 7, and with this state, the resin encapsulation is performed to form an integral seal member 11 shown in FIG. 18.

Thereafter, plural soldering bumps 5, which are external terminals, are mounted to the back face of each of the device regions 10a on the multi-chip bonded substrate 10 as shown in FIG. 19.

Then, as shown in FIG. 20, the integral seal member 11 and the multi-substrate 10 are cut and divided by using a dicing blade 6, dicing into a discrete semiconductor device. Thus, the assembly of the CSP 1 shown in FIG. 13 is completed.

As described above, the paste 3 is applied by using the semiconductor manufacturing device 21 according to this embodiment, whereby the invention can be applied for the assembly of a semiconductor device that is a semiconductor microchip 4 and uses MAP. Specifically, the paste 3 is applied by using the semiconductor manufacturing device 21 having the pump system 20 according to this embodiment, whereby a semiconductor device in which a semiconductor microchip 4 requiring the application of a trace amount of paste 3 can be assembled and produced with high reliability.

The invention made by present inventors was specifically explained above with reference to the embodiments. The invention is not limited to the aforesaid embodiments, but may be modified in various ways without departing from the spirit of the invention.

For example, although the aforesaid embodiment takes, as one example, the case where the semiconductor device is the CSP 1, the other semiconductor devices such as LGA (Land Grid Array) or QFN (Quad-Flat Non-leaded Package) may be used, so long as it may be assembled such that the semiconductor chip 4 is bonded to the plate-like member such as the multi-chip bonded substrate 10 or lead frame 24 via the paste 3 applied by the gear pump 12.

Further, the gear pump 12 explained in the embodiment may be, for example, used as a pump for applying liquid crystal in the assembly of a liquid crystal substrate.

The present invention is suitable for a semiconductor manufacturing technology using a gear pump.

What is claimed is:

1. A semiconductor manufacturing method, in which a gear structure having a non-contact gear and contact gear that are concentrically and integrally formed is used, and driving force is given to the contact gear to rotate the non-contact gear for applying a paste with the non-contact gear used as a gear pump.

2. A semiconductor manufacturing method according to claim 1, wherein the application amount of the paste is 0.01 to 0.5 ml per one application.

3. A semiconductor manufacturing method according to claim 1, wherein the application speed of the paste is 0.3 to 0.5 sec per one application.

4. A semiconductor manufacturing method according to claim 1, wherein the gear pump has a housing for accommodating the non-contact gear and the contact gear, and a part of the housing is made of a transparent plate.

5. A semiconductor manufacturing method according to claim 1, wherein the gear pump has a housing for accommodating the non-contact gear and the contact gear, and the housing is assembled so as to be dividable into three.

6. A semiconductor manufacturing method according to claim 1, wherein the gear pump is pulse-driven by a stepping motor, and the gear pump is controlled to be rotated by a drive with a pulse number of 3000 pulses or more per one rotation, thereby applying the paste.

7. A semiconductor manufacturing method according to claim 1, comprising a step of venting air in the pump toward the outside by rotating the non-contact gear, before a step of applying the paste.

8. A semiconductor manufacturing method for applying a paste by using a gear pump having a non-contact gear, wherein the gear pump is pulse-driven by a stepping motor, and the gear pump is controlled to be rotated by a drive with a pulse number of 3000 pulses or more per one rotation thereby applying the paste.

9. A semiconductor manufacturing method according to claim 8, wherein the application amount of the paste is 0.01 to 0.5 ml per one application.

10. A semiconductor manufacturing method according to claim 8, wherein the application speed of the paste is 0.3 to 0.5 sec per one application.

11. A semiconductor manufacturing method according to claim 8, wherein the gear pump has a housing for accommodating the non-contact gear, and a part of the housing is made of a transparent plate.

12. A semiconductor manufacturing method according to claim 8, wherein the gear pump has a housing for accommodating the non-contact gear, and the housing is assembled so as to be dividable into three.

13. A semiconductor manufacturing method according to claim 8, wherein driving force is given to the non-contact gear by a contact gear that is concentrically and integrally formed with the non-contact gear.

14. A semiconductor manufacturing method according to claim 8, comprising a step of venting air in the pump toward the outside by rotating the non-contact gear, before a step of applying the paste.
